(19) United States
(12) Patent Application Publication
(10) Pub. No.: US 2026/0311976 A1
(43) Pub. Date: Oct. 8, 2026

(54) DETECTING AND LOCATING ANOMALOUS PLASMA EVENTS IN MULTI-STATION PROCESSING CHAMBERS

(71) Applicant: Lam Research Corporation, Fremont, CA (US)

(72) Inventors: Casey Patrick MONTGOMERY, Portland, OR (US); Ateeq Junaid SURIA, Portland, OR (US); Niraj RANA, West Linn, OR (US); Feng BI, Lake Oswego, OR (US); Toshisato ONO, Tualatin, OR (US)

(21) Appl. No.: 19/490,272

(22) PCT Filed: Jun. 27, 2024
(86) PCT No.: PCT/US2024/035905

§ 371 Date: Dec. 4, 2025

Related U.S. Application Data
(60) Provisional application No. 63/511,608, filed on Jun. 30, 2023.

(51) Int. Cl. H01J 37/32

(52) U.S. Cl. CPC H01J 37/32935; H01J 2237/332; H01J 2237/334

(57) ABSTRACT

One example provides a processing tool comprising a processing chamber. The processing chamber comprises a plurality of processing stations and a plurality of photosensors. Each photosensor of the plurality of photosensors is arranged to view a corresponding processing station of the plurality of processing stations with no intervening processing stations between the photosensor and the corresponding processing station.

### BACKGROUND

Various semiconductor device fabrication processes can utilize a multi-station processing chamber in which plasmas can be formed at each processing station. A plasma is a gaseous state of matter that includes ionized gaseous species. Plasmas can be used for processes such as plasma enhanced chemical vapor deposition (PECVD), plasma enhanced atomic layer deposition (PEALD), and plasma etching processes such as reactive ion etching (RIE).

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a processing tool comprising a processing chamber. The processing chamber comprises a plurality of processing stations and a plurality of photosensors. Each photosensor of the plurality of photosensors is arranged to view a corresponding processing station of the plurality of processing stations with no intervening processing stations between the photosensor and the corresponding processing station.

In some examples, the processing chamber comprises a plurality of viewports, wherein each photosensor is positioned to view the corresponding processing station through a corresponding viewport.

Alternatively or additionally, in some examples, the processing tool further comprises a computing system configured to locate a processing station at which an anomalous plasma event occurs based at least upon outputs from the plurality of photosensors.

Alternatively or additionally, in some examples, the computing system is configured to locate the processing station at which the anomalous plasma event occurs by detecting an output from a photosensor of the plurality of photosensors that exceeds a threshold amplitude.

Alternatively or additionally, in some examples, the computing system is further configured to compare a duration of the output exceeding the threshold amplitude to a threshold duration, and determine that the anomalous plasma event occurred based at least upon the duration exceeding the threshold duration.

Alternatively or additionally, in some examples, the computing system is further configured to perform a responsive action based at least upon the duration.

Alternatively or additionally, in some examples, the processing tool is a plasma etching tool.

Alternatively or additionally, in some examples, the processing tool is a plasma deposition tool.

Alternatively or additionally, in some examples, the processing chamber comprises four processing stations and four photosensors.

Alternatively or additionally, in some examples, the four processing stations are arranged in a rectangular pattern, a first photosensor of the four photosensors is located on a first side of the processing chamber to view a first processing station, a second photosensor of the four photosensors is located on a second side of the processing chamber opposite the first side, and a third photosensor and a fourth photosensor are located on a third side of the processing chamber to respectively view a third processing station and a fourth processing station.

Another example provides a processing tool. The processing tool comprises a processing chamber with a plurality of plasma processing stations, a plurality of viewports, and a plurality of photosensors, each photosensor of the plurality of photosensors having a field of view through a corresponding viewport of the plurality of viewports that encompasses a corresponding plasma processing station of the plurality of plasma processing stations with no intervening processing stations. The processing tool further comprises a computing system comprising instructions executable to identify a processing station at which an anomalous plasma event occurs. The computing system further comprises instructions executable to compare outputs from the plurality of photosensors to logic states indicative of anomalous plasma events at the plurality of processing stations, and instructions executable to determine that the anomalous plasma event occurred at the selected processing station and not at other processing stations based at least upon a logic state of the selected processing station being in a first state and logic states of other processing stations being in a second state.

In some examples, the computing system further comprises instructions executable to perform a responsive action based at least upon determining that the anomalous plasma event occurred.

Alternatively or additionally, in some examples, the computing system further comprises instructions executable to compare a duration of the anomalous plasma event to a threshold duration, and perform the responsive action based at least upon the duration of the anomalous plasma event.

Alternatively or additionally, in some examples, the responsive action comprises the reduction in amplitude of a radiofrequency power source.

Alternatively or additionally, in some examples, the responsive action comprises outputting an indication that a substrate should be removed from the processing chamber.

Another example provides, on a processing tool comprising a processing chamber with a plurality of plasma processing stations, a plurality of viewports, and a plurality of photosensors, each photosensor of the plurality of photosensors having a field of view through a corresponding viewport of the plurality of viewports to a corresponding plasma processing station of the plurality of plasma processing stations with no intervening processing stations, a method of identifying a processing station at which an anomalous plasma event occurs. The method comprises receiving outputs from the plurality of photosensors, comparing the outputs to logic states indicative of anomalous plasma events at the plurality of processing stations, and based at least upon a logic state of a selected processing station being in a first state and logic states of other processing stations being in a second state, determining that the anomalous plasma event occurred at the selected processing station and not at the other processing stations.

In some examples, receiving outputs from the plurality of photosensors comprises receiving outputs from four photosensors configured to sense four plasma processing stations.

Alternatively or additionally, in some examples, comparing the outputs to logic states indicative of anomalous plasma events at the plurality of processing stations comprises, for each output, comparing an amplitude of the output to a threshold amplitude.

Alternatively or additionally, in some examples, comparing the outputs to logic states indicative of the anomalous plasma event further comprises comparing the duration of an output with an amplitude above the threshold amplitude to a threshold duration.

Alternatively or additionally, in some examples, the method further comprises performing a responsive action based at least upon the duration.

### BRIEF DESCRIPTION OF THE DRAWINGS

FIG. 1A shows an arrangement of photosensors to sense anomalous plasma events in a multi-station processing chamber.

FIG. 1B shows an example logic table useable to detect anomalous plasma events using the arrangement of photosensors of FIG. 1A.

FIG. 2A shows an example arrangement of photosensors to sense anomalous plasma events in a multi-station processing chamber, wherein each photosensor has a view of a corresponding plasma processing station with no intervening processing stations.

FIG. 2B shows an example logic table useable to detect anomalous plasma events using the arrangement of photosensors of FIG. 2A.

FIG. 3 shows an example detection and location of an anomalous plasma event using the arrangement of photosensors of FIG. 1A.

FIG. 4 shows an example detection and location of an anomalous plasma event using the arrangement of photosensors of FIG. 2A.

FIG. 5 shows an example representation of a photosensor output.

FIG. 6 shows an example processing tool.

FIG. 7 shows a flow diagram depicting an example method for detecting an anomalous plasma event.

FIG. 8 shows a block diagram of an example computing system.

### DETAILED DESCRIPTION

As introduced above, a substrate processing tool can comprise a multi-station processing chamber in which plasmas are used to process substrates at the processing stations. In such tools, a power source (e.g. a radiofrequency power source) can be utilized to provide a signal to form the plasma at each station. In a multi-station processing chamber, a same radiofrequency input signal can provide radiofrequency power to the multiple processing stations. An amplitude of the radiofrequency signal can be controlled to provide sufficient energy to form a plasma within a processing chamber while avoiding anomalous conditions within the processing chamber. Anomalous conditions can include, for example, formation of an electrical arc, or other type of visible event generated by an electrical discharge between or among two or more localized regions within a processing station. Anomalous conditions can bring about excessive heating and excessive electrical current. Anomalous conditions also can include instabilities in a plasma due to particles present in a processing chamber. Anomalous conditions also can include abrupt changes in gas pressure and/or gas composition, and failures of radiofrequency power generating circuitry. The occurrence of an anomalous condition is referred to herein as an anomalous plasma event.

An anomalous plasma event can cause a substrate undergoing fabrication to be exposed to elevated temperatures. An anomalous plasma event also can expose a substrate to an electrical current sufficient to damage circuits being manufactured on the substrate. In such instances, it can be necessary to remove the potentially damaged substrate from the processing chamber so that the substrate can undergo a metrology process. A metrology process can include performing electrical measurements, physical inspections, and/or other processes. In some instances, formation of an electrical arc can give rise to significant damage, which can result in scrapping or discarding one or more potentially damaged integrated circuit wafers. Additionally, in some instances, formation of an electrical arc can bring about damage to the processing chamber itself, which can necessitate costly repair as well as the temporary decommissioning of the processing chamber.

Timely detection of an anomalous plasma event can allow responsive action to be performed sufficiently quickly to prevent additional damage from occurring. For example, upon detecting an anomalous plasma event, a radiofrequency power source can be interrupted, reduced in amplitude, or adjusted in some other manner. Such interruption, reduction in amplitude, or other type of adjustment of a radiofrequency power source can help to minimize, or in some cases avoid entirely, damage to a substrate being processed, as well as damage to the processing chamber itself. In addition, by detecting a particular processing station of a multi-station processing chamber at which an anomalous plasma event has occurred, a separate metrology process can be performed on the substrate at that particular processing station. Performing a metrology process on a single wafer can be advantageous compared to performing a metrology process on all substrates present within the multi-station processing chamber when the anomalous plasma event was detected.

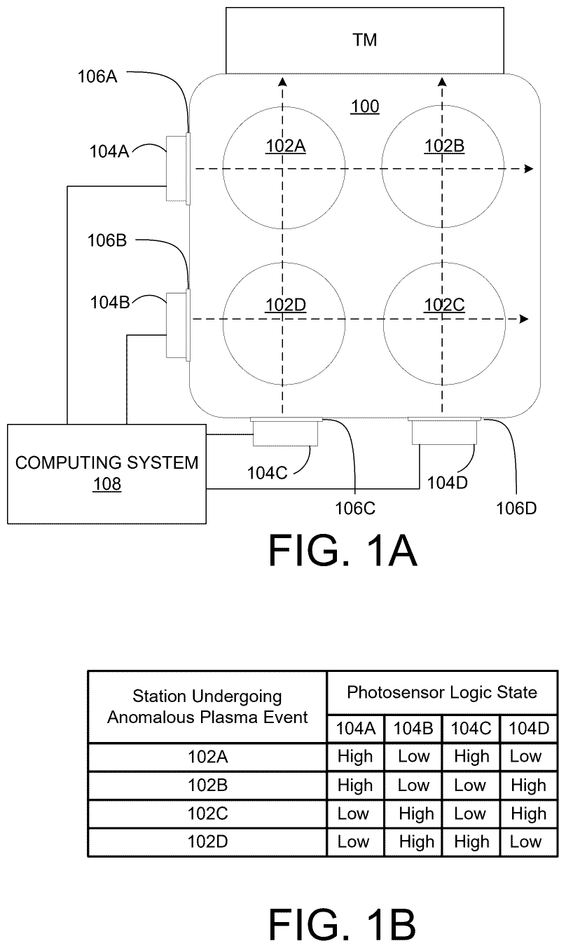

Anomalous plasma events in a multi-station processing chamber can be detected and located using a plurality of photosensors. FIG. 1A depicts an arrangement of photosensors for a four station processing chamber 100. In this example, four processing stations (102A, 102B, 102C, 102D) are arranged in an approximately square pattern. Further, two photosensors 104A, 104B are arranged along a first side of the square arrangement of processing stations 102A, 102B, 102C, 102D. Also, two photosensors 104C, 104D are arranged along a second side of the square arrangement of processing stations 102A, 102B, 102C, 102D. Lines of sight of each photosensor 104A, 104B, 104C, 104D are shown by dashed-line arrows. The photosensors 104A, 104B, 104C, 104D can view the processing stations through viewports 106A, 106B, 106C, 106D formed in the processing chamber 100.

In the arrangement of FIG. 1A, a computing system 108 receives the outputs of the photosensors 104A, 104B, 104C, 104D. Computing system 108 can detect and locate an anomalous plasma event based at least upon the outputs of the photosensors 104A, 104B, 104C, 104D according to the logic table of FIG. 1B. As shown, anomalous plasma events are located for each processing station 102A, 102B, 102C, 102D by a different combination of two high and two low photosensor outputs. The four processing stations 102A, 102B, 102C, 102D can represent a multi-station processing chamber of any suitable type of tool, including PEALD, PECVD, and plasma etching tools.

In the arrangement of FIG. 1A, processing stations 102A, 102C, and 102D are all located directly adjacent to at least one photosensor, with no intervening processing stations. More particularly, processing station 102A is directly adjacent to photosensor 104A, processing station 102C is directly adjacent to photosensor 104D, and processing station 102D is directly adjacent to both photosensors 104B and 104C. However, processing station 102B is not directly adjacent to any photosensor. As such, the sensitivity of detecting anomalous plasma events using the arrangement of FIG. 1A and photosensor logic states of FIG. 1B can be less sensitive for processing station 102B than for the other processing stations.

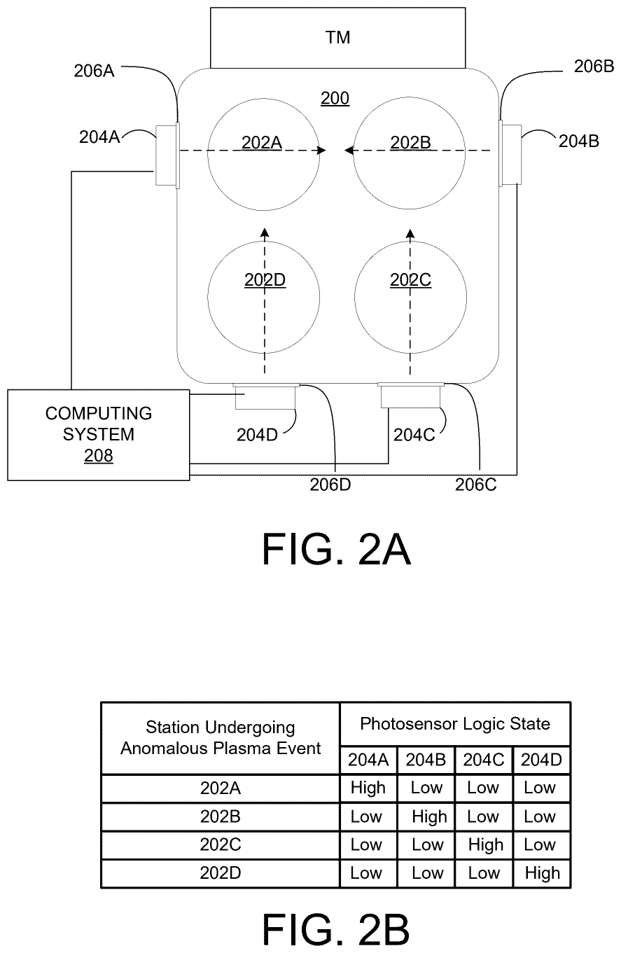

Accordingly, FIG. 2A depicts an example processing chamber 200 with another example arrangement of photosensors. In the arrangement of FIG. 2A, processing station 202A is directly adjacent to photosensor 204A, processing station 202B is directly adjacent to photosensor 204B, processing station 202C is directly adjacent to photosensor 204C, and processing station 202D is directly adjacent to photosensor 204D. Each photosensor can view the corresponding processing station directly adjacent via corresponding viewports (206A, 206B, 206C, 206D), with no intervening processing stations between the photosensor and the corresponding processing station.

FIG. 2B depicts a logic table illustrating logic states of the photosensors 204A, 204B, 204C, 204D of FIG. 2B that are indicative of anomalous plasma events at the plurality of processing stations 202A, 202B, 202C, 202D. As shown, the depicted computing system 208 can detect and locate an anomalous plasma event at processing station 202A by a high logic state output by photosensor 204A, an anomalous plasma event at processing station 202B by a high logic state output by photosensor 204B, an anomalous plasma event at processing station 202C by a high logic state output by photosensor 204C, and an anomalous plasma event at processing station 202D by a high logic state output by photosensor 204D. In this arrangement, anomalous plasma events can be detected at each processing station 202A, 202B, 202C, 202D with similar sensitivity as at each other processing station 202A, 202B, 202C, 202D. Further, the simplified logic table of FIG. 2B for detecting the location of an anomalous plasma event can provide for less ambiguity in determining and reporting the relevant processing station 202A, 202B, 202C, 202D. These factors can help decrease tool downtime, reduce an incidence of scrapped substrates, and also reduce hardware replacement expenses (e.g. arising from damage to processing station showerheads from arcing). While the depicted example includes four processing stations 202A, 202B, 202C, 202D in a processing chamber 200, in other examples, a multi-station processing chamber can include any other suitable number of processing stations in a processing chamber, such as two, three, or five or more processing stations, as well as corresponding viewports and photosensors.

In the example of FIG. 2, a first photosensor of the four photosensors is located on a first side of the processing chamber to view a first processing station, a second photosensor of the four photosensors is located on a second side of the processing chamber opposite the first side, and a third photosensor and a fourth photosensor are located on a third side of the processing chamber to respectively view a third processing station and a fourth processing station. In other examples, four photosensors can have another suitable arrangement to directly view four corresponding processing stations.

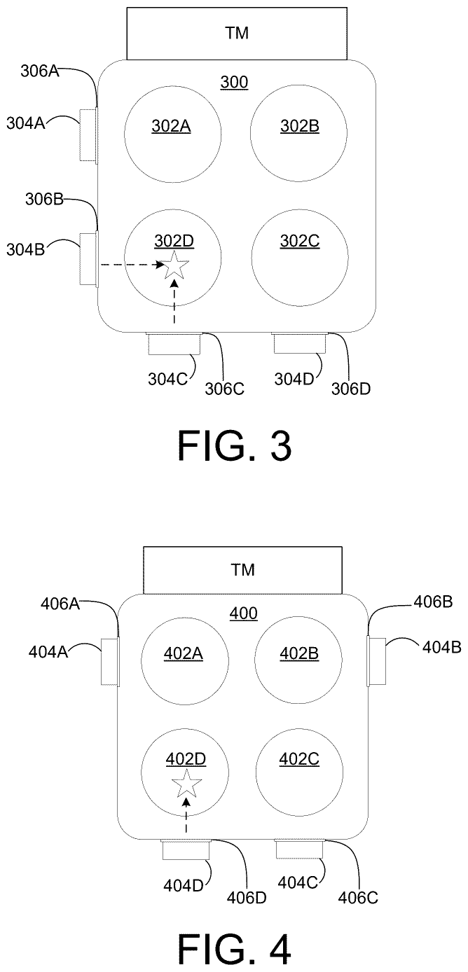

FIGS. 3 and 4 compare how an anomalous plasma event in processing chamber 300 at processing station 302D is detected using the example of FIGS. 1A-1B compared to the example of FIGS. 2A-2B. First, FIG. 3 depicts the photosensor arrangement of FIG. 1A. Here, the anomalous plasma event can be detected and located by a combination of high outputs from photosensors 304B and 304C and low outputs from photosensors 304A and 304D. In contrast, FIG. 4 depicts the photosensor arrangement of FIG. 2A. Here, the anomalous plasma event can be detected and located by a combination of a high output from photosensor 404D, in combination with low outputs from photosensors 404A, 404B, and 404C.

The photosensor arrangement of FIG. 2A can be implemented in a processing chamber originally set up with the arrangement of FIG. 1A by moving photosensor 104B of FIG. 1A to a location next to processing station 102B, and swapping the locations of photosensors 104C and 104D. This can be achieved with a relatively small number of new parts (e.g. new cables to accommodate the moved photosensors and thermal management system updates (e.g. new or different arrangement of processing chamber heat shields). As stated above, this change in photosensor arrangement of FIG. 2A simplifies the logic table for detecting an anomalous plasma event.

Photosensor output thresholds used to define logic high and logic low levels may be determined experimentally, by predictive/statistical modeling, or by other methods. The logic high and logic low thresholds further can be set to define a buffer region between the logic high and logic low thresholds. This can help, for example, mitigate possible noise from the photosensor output. For example, if an output from a photosensor such as photosensor 404D in FIG. 4 exceeds the logic low threshold but does not exceed the logic high threshold, then the output may indicate noise. However, if the amplitude of an output from a photosensor exceeds both the logic high and logic low thresholds, then the output may indicate an anomalous plasma event. In some examples, a same threshold high and a same threshold low can be used for each of the plurality of photosensors. In other examples, different threshold highs and different threshold lows may be used for different processing stations.

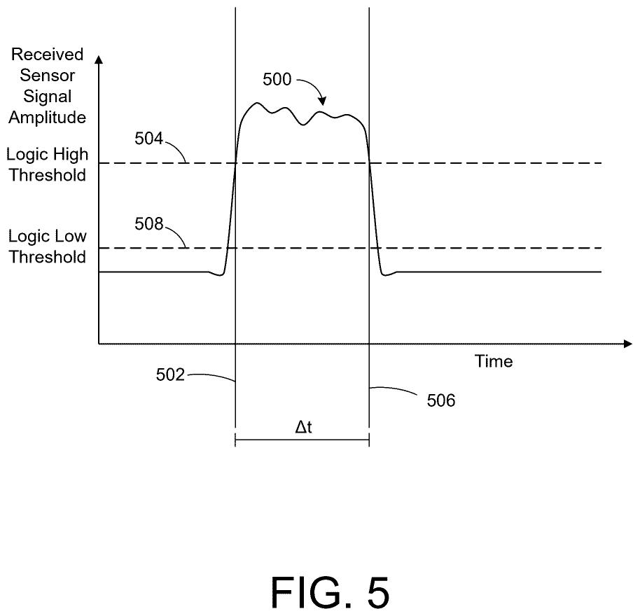

FIG. 5 shows an example representation of a photosensor output 500 from a photosensor observing a processing station. The output can correspond, for example, to outputs from photosensor 404D in FIG. 4 depicting an anomalous plasma event occurring at processing station 402D. The amplitude of the output 500 at time 502 rises above a logic high threshold 504. Further, at time 506, the amplitude of the output 500 decreases to below a logic low threshold 508. According to the logic table in FIG. 2B for the photosensor arrangement depicted in FIG. 4, the logic table indicates an anomalous plasma event occurring at processing station 402D between time 502 and time 506.

Durations of anomalous plasma events can vary. In the example of FIG. 5, the duration Δt of the anomalous plasma event is from time 502 to time 506. In some examples, a responsive action to perform for an anomalous plasma event can vary based upon comparing the duration of the anomalous plasma event to one or more duration thresholds. The duration threshold(s) can be determined experimentally, using predictive/statistical modeling, or by other methods. As one example, an anomalous plasma event with a duration of less than 1 microsecond (μs) may be unlikely to result in damage to the substrate or processing chamber for an example process and/or processing tool. As such, an anomalous plasma event with a duration of less than 1 μs in the example process and/or processing tool can trigger a responsive action such as logging of the detected anomalous plasma event, but not adjusting plasma power or prompting removal of the affected substrate from the processing chamber. On the other hand, an anomalous plasma event with a duration of greater than 1 μs may be likely to result in damage to the substrate. As such, a responsive action to an anomalous plasma event with a duration of greater than 1 μs can be to output an indication that a substrate should be removed from the processing chamber for metrology. Further, an anomalous plasma event with a duration of greater than 1 μs also may be likely to result in damage to a processing chamber. As such, a responsive action to an anomalous plasma event with a duration of greater than 1 μs alternatively or additionally can include reducing or suspending power used to form the plasma. Accordingly, the duration of the photosensor output indicating an anomalous plasma event can be used to select an appropriate responsive action or actions. While a 1 μs duration threshold is described in this example, a duration threshold can have any other suitable value in other examples.

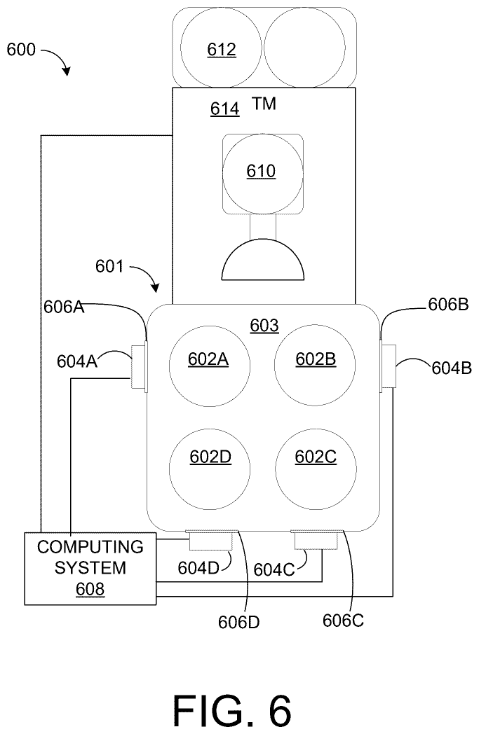

FIG. 6 shows a schematic view of an example processing tool 600 comprising a processing module 601. Processing module 601 includes a four-station processing chamber 603. Processing chamber 603 comprises processing stations 602A, 602B, 602C, 602D arranged in an approximately rectangular pattern. The four processing stations 602A, 602B, 602C, 602D can represent plasma processing stations in a multi-station processing chamber 603 of any suitable type of processing tool 600, including PEALD, PECVD, and plasma etching tools. Photosensors 604A, 604B, 604C, and 604D are arranged to each have an unobstructed view through viewports 606A, 606B, 606C, 606D to sense the respective corresponding processing stations 602A, 602B, 602C, 602D. Computing system 608 can be configured to detect and locate anomalous plasma events based at least upon the logic state outputs of photosensors 604A, 604B, 604C, 604D.

Processing tool 600 further comprises a front end module 612, and a transfer module 614 comprising a handler robot 610. The front end module 612 is configured as an interface for inputting substrates into and outputting substrates from processing tool 600. The front end module 612 can include one or more load ports each configured to receive a FOUP (front opening unified pod), one or more load locks configured to bring substrates from atmospheric conditions to low pressure conditions, and other suitable equipment. The transfer module 614 is configured to receive substrates from the front end module 612, and to transfer the substrates to the processing chamber 603 using the handler robot 610. While the processing tool 600 is shown as comprising a single processing module 601, in other examples, a processing tool 600 can have two or more processing modules each attached to a transfer module.

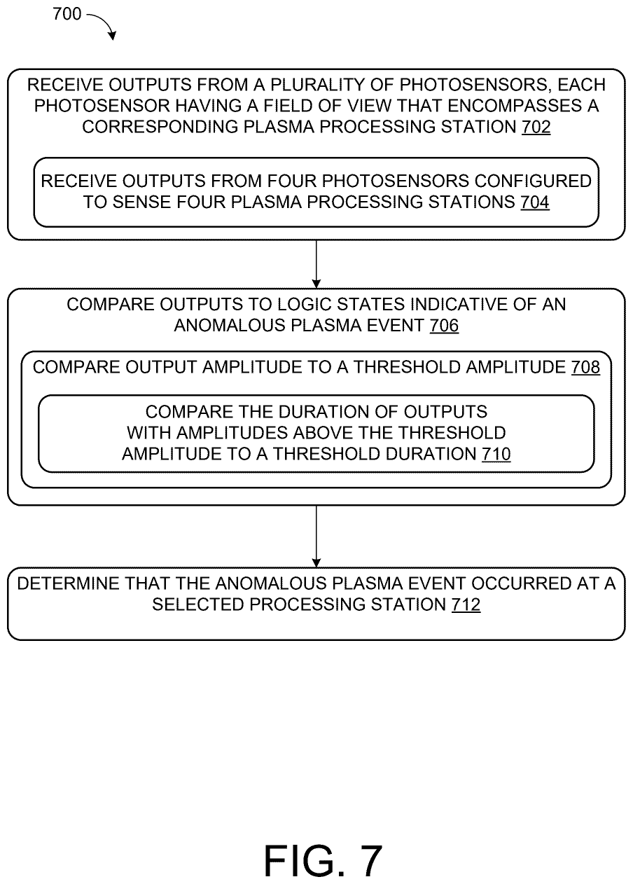

FIG. 7 shows a flow diagram illustrating an example method 700 for the determination of an anomalous plasma event. Method 700 can be performed using computing system 608 of processing tool 600, for example. The method comprises, at 702, receiving outputs from a plurality of photosensors, each photosensor having a field of view through a corresponding viewport that encompasses a corresponding plasma processing station. In some examples, receiving the output from the plurality of photosensors can comprise, at 704, receiving outputs from four photosensors configured to sense four corresponding plasma processing stations. In other examples, any other suitable number of photosensors can be used to sense a same number of corresponding processing stations.

Method 700 further comprises, at 706, comparing the outputs of the plurality of photosensors to logic states indicative of anomalous plasma events at the plurality of processing stations. FIG. 2B shows an example table of such logic states. Comparing the outputs of the photosensors to the logic states can comprise, for example, comparing the amplitude of each output to a corresponding threshold amplitude, at 708. In some examples, a same threshold is used for all processing stations. In other examples, different thresholds may be used for different processing stations (e.g. due to calibrations, different optical path lengths, and/or other factors). Further, in some such examples, comparing the outputs of the photosensors to the logic states indicative of the anomalous plasma events at the processing stations can comprise determining a duration for which an amplitude of an output of a processing station is above the threshold amplitude, and comparing the duration to a threshold duration, at 710. As described above, different responsive actions may be performed for anomalous plasma events of different durations.

Continuing, method 700 further comprises, at 712, determining that the anomalous plasma event occurs at a selected processing station based at least upon comparing the outputs of the photosensor to the logic states indicative of the anomalous plasma event.

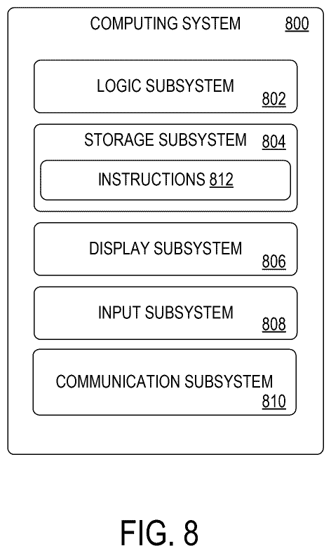

FIG. 8 schematically shows a non-limiting example of a computing system 800 that can enact one or more of the methods and processes described above. Computing system 800 is shown in simplified form. Computing system 800 can take the form of one or more personal computers, workstations, computers integrated with substrate processing tools, and/or network accessible server computers.

Computing system 800 includes a logic subsystem 802 and a storage subsystem 804. Computing system 800 can optionally include a display subsystem 806, input subsystem 808, communication subsystem 810, and/or other components not shown in FIG. 8. The computing systems 108, 208 and 608 of FIGS. 1A-2A, 2A-2B, and 6, are examples of computing system 800.

Logic subsystem 802 includes one or more physical devices configured to execute instructions. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic subsystem can include one or more processors configured to execute software instructions. Additionally or alternatively, the logic subsystem can include one or more hardware or firmware logic subsystems configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 804 includes one or more physical devices configured to hold instructions 812 executable by the logic subsystem to implement the methods and processes described herein. When such methods and processes are implemented, the state of storage subsystem 804 can be transformed—e.g., to hold different data.

Storage subsystem 804 can include removable and/or built-in devices. Storage subsystem 804 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 804 can include volatile, nonvolatile, dynamic, static, read/write, read-only, random-access, sequential-access, location-addressable, file-addressable, and/or content-addressable devices.

It will be appreciated that storage subsystem 804 includes one or more physical devices. However, aspects of the instructions described herein alternatively can be propagated by a communication medium (e.g., an electromagnetic signal, an optical signal, etc.) that is not held by a physical device for a finite duration.

Aspects of logic subsystem 802 and storage subsystem 804 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 806 can be used to present a visual representation of data held by storage subsystem 804. This visual representation can take the form of a graphical user interface (GUI). As the herein described methods and processes change the data held by the storage subsystem, and thus transform the state of the storage subsystem, the state of display subsystem 806 can likewise be transformed to visually represent changes in the underlying data. Display subsystem 506 can include one or more display devices utilizing virtually any type of technology. Such display devices can be combined with logic subsystem 802 and/or storage subsystem 804 in a shared enclosure, or such display devices can be peripheral display devices.

When included, input subsystem 808 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on-or off-board. Example NUI componentry can include a microphone for speech and/or voice recognition, and an infrared, color, stereoscopic, and/or depth camera for machine vision and/or gesture recognition.

When included, communication subsystem 810 can be configured to communicatively couple computing system 800 with one or more other computing devices. Communication subsystem 810 can include wired and/or wireless communication devices compatible with one or more different communication protocols. As non-limiting examples, the communication subsystem can be configured for communication via a wireless telephone network, or a wired or wireless local-or wide-area network. In some examples, the communication subsystem can allow computing system 800 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A processing tool, comprising:
a processing chamber comprising a plurality of processing stations; and
a plurality of photosensors, wherein each photosensor of the plurality of photosensors is arranged to view a corresponding processing station of the plurality of processing stations with no intervening processing stations between the photosensor and the corresponding processing station.

2. The processing tool of claim 1, wherein the processing chamber comprises a plurality of viewports, wherein each photosensor is positioned to view the corresponding processing station through a corresponding viewport.

3. The processing tool of claim 1, further comprising a computing system configured to locate a processing station at which an anomalous plasma event occurs based at least upon outputs from the plurality of photosensors.

4. The processing tool of claim 3, wherein the computing system is configured to locate the processing station at which the anomalous plasma event occurs by detecting an output from a photosensor of the plurality of photosensors that exceeds a threshold amplitude.

5. The processing tool of claim 4, wherein the computing system is further configured to compare a duration of the output exceeding the threshold amplitude to a threshold duration, and determine that the anomalous plasma event occurred based at least upon the duration exceeding the threshold duration.

6. The processing tool of claim 5, wherein the computing system is further configured to perform a responsive action based at least upon the duration.

7. The processing tool of claim 1, wherein the processing tool is a plasma etching tool.

8. The processing tool of claim 1, wherein the processing tool is a plasma deposition tool.

9. The processing tool of claim 1, wherein the processing chamber comprises four processing stations and four photosensors.

10. The processing tool of claim 9, wherein
the four processing stations are arranged in a rectangular pattern,
a first photosensor of the four photosensors is located on a first side of the processing chamber to view a first processing station,
a second photosensor of the four photosensors is located on a second side of the processing chamber opposite the first side, and
a third photosensor and a fourth photosensor are located on a third side of the processing chamber to respectively view a third processing station and a fourth processing station.

11. A processing tool comprising:
a processing chamber with a plurality of plasma processing stations, a plurality of viewports, and a plurality of photosensors, each photosensor of the plurality of photosensors having a field of view through a corresponding viewport of the plurality of viewports that encompasses a corresponding plasma processing station of the plurality of plasma processing stations with no intervening processing stations; and
a computing system comprising instructions executable to identify a processing station at which an anomalous plasma event occurs, the instructions comprising:
instructions executable to compare outputs from the plurality of photosensors to logic states indicative of anomalous plasma events at the plurality of processing stations, and
instructions executable to determine that the anomalous plasma event occurred at the selected processing station and not at other processing stations based at least upon a logic state of the selected processing station being in a first state and logic states of other processing stations being in a second state.

12. The processing tool of claim 11, wherein the computing system further comprises instructions executable to perform a responsive action based at least upon determining that the anomalous plasma event occurred.

13. The processing tool of claim 12, wherein the computing system further comprises instructions executable to compare a duration of the anomalous plasma event to a threshold duration, and perform the responsive action based at least upon the duration of the anomalous plasma event.

14. The processing tool of claim 12, wherein the responsive action comprises a reduction in amplitude of a radiofrequency power source.

15. The processing tool of claim 12, wherein the responsive action comprises outputting an indication that a substrate should be removed from the processing chamber.

16. On a processing tool comprising a processing chamber with a plurality of plasma processing stations, a plurality of viewports, and a plurality of photosensors, each photosensor of the plurality of photosensors having a field of view through a corresponding viewport of the plurality of viewports to a corresponding plasma processing station of the plurality of plasma processing stations with no intervening processing stations, a method identifying a processing station at which an anomalous plasma event occurs, the method comprising:
receiving outputs from the plurality of photosensors;
comparing the outputs to logic states indicative of anomalous plasma events at the plurality of processing stations; and
based at least upon a logic state of a selected processing station being in a first state and logic states of other processing stations being in a second state, determining that the anomalous plasma event occurred at the selected processing station and not at the other processing stations.

17. The method of claim 16, wherein receiving outputs from the plurality of photosensors comprises receiving outputs from four photosensors configured to sense four plasma processing stations.

18. The method of claim 16, wherein comparing the outputs to logic states indicative of anomalous plasma events at the plurality of processing stations comprises, for each output, comparing an amplitude of the output to a threshold amplitude.

19. The method of claim 18, wherein comparing the outputs to logic states indicative of the anomalous plasma event further comprises comparing the duration of an output with an amplitude above the threshold amplitude to a threshold duration.

20. The method of claim 19, further comprising performing a responsive action based at least upon the duration.
